(19) United States
(12) Patent Application Publication
(10) Pub. No.: US 2015/0243492 A1
(43) Pub. Date: Aug. 27, 2015

(54) APPARATUS AND METHOD OF FORMING SILICON NITRIDE FILM

(71) Applicant: TOKYO ELECTRON LIMITED, Tokyo (JP)

(72) Inventors: Tetsushi OZAKI, Nirasaki City (JP); Yoshitaka MORI, Nirasaki City (JP)

(21) Appl. No.: 14/629,977

(22) Filed: Feb. 24, 2015

(30) Foreign Application Priority Data
Feb. 27, 2014 (JP) 2014-036562

(51) Int. Cl. H01L 21/02; C23C 16/455; C23C 16/34

(52) U.S. Cl. CPC H01L 21/0217; C23C 16/345; C23C 16/45544; C23C 16/45527; H01L 21/02263

(57) ABSTRACT

An apparatus of forming silicon nitride film includes: a reaction chamber accommodating a workpiece; a source gas supply unit supplying a source gas into the reaction chamber; a nitriding gas supply unit supplying a nitriding gas into the reaction chamber; a controller configured to form the silicon nitride film on the workpiece by controlling the source gas supply unit such that the silicon is adsorbed to the workpiece by supplying the source gas into the reaction chamber, and controlling the nitriding gas supply unit such that the silicon adsorbed to the workpiece is nitrided by supplying the nitriding gas into the reaction chamber; a flow path where the nitriding gas supplied into the reaction chamber flows until reaching the workpiece; and members arranged in the flow path. The members have a coating with platinum-group metals that activates the nitriding gas supplied from the nitriding gas supply unit.

### CROSS-REFERENCE TO RELATED APPLICATION

This application claims the benefit of Japanese Patent Application No. 2014-036562, filed on Feb. 27, 2014, in the Japan Patent Office, the disclosure of which is incorporated herein in its entirety by reference.

### TECHNICAL FIELD

The present disclosure relates to an apparatus and method of forming a silicon nitride film.

### BACKGROUND

According to a miniaturization of semiconductor devices process, technologies for forming silicon nitride films (Si₃N₄ film) having high-quality at low temperature have been developed. For example, it is known in the industry to use a batch-type remote plasma treatment apparatus including: a process tube for configuring a process chamber which processes a plurality of wafers in a lump; a gas supply unit for supplying a process gas into the process chamber; an exhaust unit for exhausting the interior of the process chamber; and a pair of discharge electrodes for applying high-frequency power which excites the process gas by generating plasma within the process chamber.

However, in the case of a film that is formed by using a plasma technique, there is a problem in that plasma damage occurs. The plasma damage is closely related to the intensity of generated plasma (activation force of ammonia molecules). For example, if a radio frequency (RF) power increases in order to raise a nitriding degree, nitriding time is reduced or plasma irradiating time extends, the plasma damage may increase.

Moreover, for example, in the case of a film formation device which has a plasma generator at an edge portion of a semiconductor wafer and supplies plasma-activated ammonia towards the center of the semiconductor wafer, the nitriding degree at the center of the semiconductor wafer near plasma generated portions may differ from the nitriding degree at the edge of the semiconductor wafer spaced from the plasma generated portions. Thus, there are differences in the thickness of silicon nitride film and in-plane inclination of film quality. This may result from a phenomenon that the ammonia molecules activated at the edge of the semiconductor wafer are deactivated before reaching the center of the semiconductor wafer. Furthermore, in terms of the inter-plane direction, an uneven profile of the thickness or quality of silicon nitride film may occur due to the uneven profile of plasma.

Accordingly, when ammonia is activated by using plasma, it is difficult to control the balance of the nitriding degrees of the in-plane and the inter-plane of the semiconductor wafer. In order to form a silicon nitride film having in-plane uniformity and inter-plane uniformity, it is difficult to achieve reduction of the nitriding time to avoid plasma damage.

### SUMMARY

The present disclosure provides an apparatus and method of forming a silicon nitride film which can form a silicon nitride film having high-quality at a low temperature without causing plasma damage.

According to one embodiment of the present disclosure, an apparatus of forming a silicon nitride film includes: a reaction chamber accommodating a workpiece; a source gas supply unit configured to supply a source gas containing silicon into the reaction chamber; a nitriding gas supply unit configured to supply a nitriding gas into the reaction chamber; a controller configured to form the silicon nitride film on the workpiece by controlling the source gas supply unit such that the silicon is adsorbed to the workpiece accommodated in the reaction chamber by supplying the source gas into the reaction chamber, and controlling the nitriding gas supply unit such that the silicon adsorbed to the workpiece is nitrided by supplying the nitriding gas into the reaction chamber; a flow path where the nitriding gas supplied into the reaction chamber flows until reaching the workpiece; and members arranged in the flow path. The members have a coating with platinum-group metals that activates the nitriding gas supplied from the nitriding gas supply unit.

According to another embodiment of the present disclosure, a method of forming a silicon nitride film includes: adsorbing silicon to a workpiece by supplying a silicon source gas containing silicon into a reaction chamber accommodating the workpiece, activating the supplied silicon source gas, and reacting the activated silicon source gas with the workpiece; and nitriding by supplying a nitriding gas into the reaction chamber and activating the supplied nitriding gas to react the activated nitriding gas with silicon adsorbed to the workpiece. In nitriding, the supplied nitriding gas is activated by coating members arranged in a flow path where the nitriding gas supplied into the reaction chamber flows until reaching the workpiece with platinum-group metals.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 illustrates a processing apparatus according to one embodiment of the present disclosure.

FIG. 2 is a diagram showing a configuration of a controller shown in FIG. 1.

FIG. 3 is a view explaining a method of forming a silicon nitride film according to one embodiment of the present disclosure.

FIG. 4 illustrates wafers coated with platinum-group elements, oxides thereof and the like and locations of monitor wafers.

FIG. 5 is a graph illustrating thicknesses of the silicon nitride films formed on the monitor wafers for each location, respectively.

### DETAILED DESCRIPTION

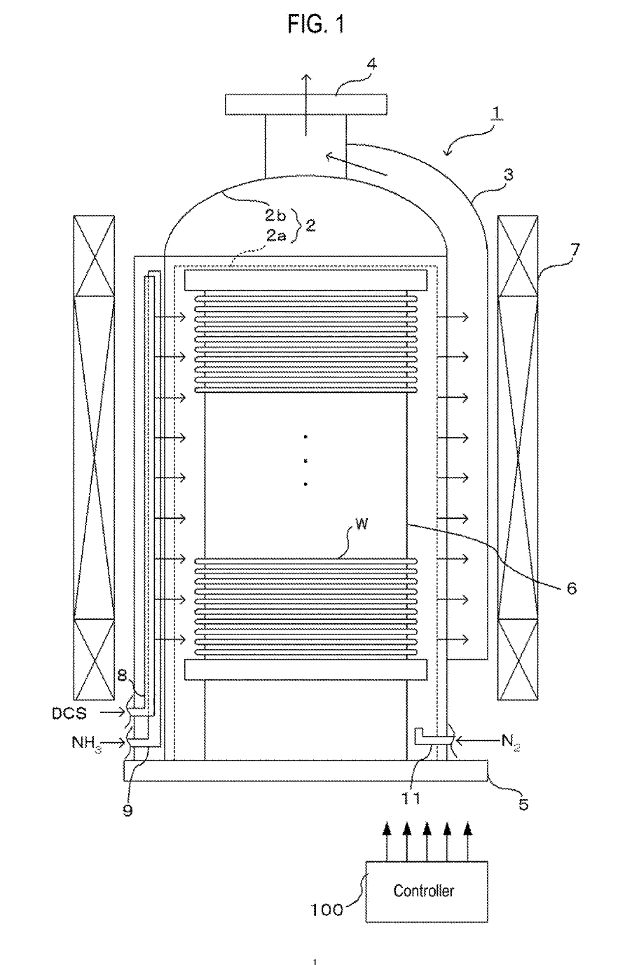

An apparatus and method of forming a silicon nitride film according to some embodiments of the present disclosure will be described in detail. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In these embodiments, description will be given by way of an example where a batch-type vertical processing apparatus is used as an apparatus of forming silicon nitride film of the present disclosure and an interior of a nitriding gas supply pipe for supplying a nitriding gas (ammonia) is coated with platinum-group metals. FIG. 1 illustrates a processing apparatus according to one embodiment of the present disclosure.

As shown in FIG. 1, the processing apparatus 1 includes a reaction tube 2, a longitudinal direction of which extends in the vertical direction. The reaction tube 2 has a double tube structure which includes an inner tube 2a and a roofed outer tube 2b configured to cover the inner tube 2a and separated a predetermined distance from the inner tube 2a. Sidewalls of the inner tube 2a and the outer tube 2b have a plurality of openings as indicated by arrows in FIG. 1. The inner tube 2a and the outer tube 2b are made of a material having excellent properties in terms of heat resistance and corrosion resistance, for example, quartz.

The reaction tube 2 is provided at one side thereof with an exhaust unit 3 that exhausts gas from the reaction tube 2. The exhaust unit 3 extends upward along the reaction tube 2 and communicates with the reaction tube 2 through the openings formed in the sidewall of the reaction tube 2. The exhaust unit 3 is connected at an upper end thereof to an exhaust port 4 arranged at an upper portion of the reaction tube 2. An exhaust pipe (not shown) is connected to the exhaust port 4. Pressure regulating mechanisms such as a valve (not shown) and a vacuum pump 127 described below are disposed in the exhaust pipe. By virtue of the pressure regulating mechanisms, a gas supplied from one side of the sidewall of the outer tube 2b (a source gas supply pipe 8) is exhausted to the exhaust pipe through the inner tube 2a, the other side of sidewall of the outer tube 2b, the exhaust unit 3, and the exhaust port 4. Thus, the interior of the reaction tube 2 is controlled to a desired pressure (vacuum degree).

A lid 5 is disposed below the reaction tube 2. The lid 5 is made of a material having excellent properties in terms of heat resistance and corrosion resistance, for example, quartz. The lid 5 is configured to be movable up and down by a boat elevator 128 described below. When the lid 5 is moved up by the boat elevator 128, a lower end (furnace port) of the reaction tube 2 is closed. When the lid 5 is moved down by the boat elevator 128, the lower end (furnace port) of the reaction tube 2 is open.

A wafer boat 6 is mounted on the lid 5. The wafer boat 6 is made of, for example, quartz. The wafer boat 6 is configured to accommodate a plurality of semiconductor wafers W such that the semiconductor wafers W are separated a predetermined distance from each other in the vertical direction. Furthermore, a heat insulating container which prevents reduction in internal temperature of the reaction tube 2 from the furnace port of the reaction tube 2 or a rotary table on which the wafer boat 6 for accommodating the semiconductor wafers W may be rotatably mounted on the rotary table may be disposed on the lid 5. The wafer boat 6 may be mounted on the heat insulating container or the rotary table. In this case, it is easy to uniformly control the temperature of the semiconductor wafers W accommodated within the wafer boat 6.

In the vicinity of the reaction tube 2, heaters 7 for temperature elevation formed of, for example, resistive heating elements, are disposed so as to surround the reaction tube 2. The interior of the reaction tube 2 is heated to a predetermined temperature by the heaters 7. As a result, the semiconductor wafers W accommodated within the reaction tube 2 are heated to a predetermined temperature.

The source gas supply pipe 8 for supplying a source gas into the reaction tube 2 (the outer tube 2b) is inserted into the reaction tube 2 through a side surface near the lower end of the reaction tube 2. The source gas is a Si source for adsorbing a source (Si) to a workpiece. The source gas is used in an adsorption step described below. Examples of the Si source may include a silicon (Si) containing gas, for example, dichlorosilane (DCS: SiH₂Cl₂), hexachlorodisilane (HCD: Si₂Cl₆), and tetrachlorosilane (SiCl₄). In this example, DCS is used as the Si source.

A plurality of supply holes is formed in the source gas supply pipe 8 to be arranged at predetermined intervals in the vertical direction. The source gas is supplied into the reaction tube 2 (the outer tube 2b) through the supply holes. Thus, as indicated by arrows in FIG. 1, the source gas is supplied into the reaction tube 2 from a plurality of places arranged in the vertical direction.

Moreover, a nitriding gas supply pipe 9 for supplying nitriding gas into the reaction tube 2 (the outer tube 2b) is inserted into the reaction tube 2 through the side surface near the lower end of the reaction tube 2. The nitriding gas is used as a gas for nitriding the source (Si) adsorbed to the workpiece and used at a nitriding step described below. For example, the nitriding gas may include ammonia (NH₃).

Similar to the source gas supply pipe 8, a plurality of supply holes is formed in the nitriding gas supply pipe 9 to be arranged at predetermined intervals in the vertical direction. The nitriding gas is supplied into the reaction tube 2 (the outer tube 2b) through the supply holes. The interior (inner wall) of nitriding gas supply pipe 9 is coated with platinum-group metals. Examples of the platinum-group metals may include metals made of platinum-group elements, i.e., ruthenium (Ru), rhodium (Rh), palladium (Pd), osmium (Os), iridium (Ir), platinum (Pt) and oxides of these platinum-group elements. When the nitriding gas, for example, ammonia, is supplied into the nitriding gas supply pipe 9, ammonia is decomposed by catalysis and thermal effect in the interior of the nitriding gas supply pipe 9 to thereby be activated. Thus, ammonia supplied from the nitriding gas supply pipe 9 is supplied into the reaction tube 2 (semiconductor wafers W) in an activated state.

Moreover, the catalysis of platinum-group metals may deteriorate when the interior of the coated nitriding gas supply pipe 9 is exposed to ammonia gas or the silicon nitride film is formed. In this case, it is possible to recover the catalytic effect by flowing an oxidizing agent to the nitriding gas supply pipe 9 to oxidize platinum-group metals or by performing dry cleaning.

Furthermore, a nitrogen gas supply pipe 11 for supplying nitrogen (N₂) as a diluting gas and a purge gas into the reaction tube 2 (the outer tube 2b) is inserted into the reaction tube 2 through the side surface near the lower end of the reaction tube 2.

The source gas supply pipe 8, the nitriding gas supply pipe 9, and the nitrogen gas supply pipe 11 are connected to gas supply sources (not shown) through a mass flow controller (MFC) 125 described below.

Moreover, a plurality of temperature sensors 122, for example, thermocouples, for measuring the internal temperature of the reaction tube 2 and a plurality of pressure gauges 123 for measuring the internal pressure of the reaction tube 2 are disposed within the reaction tube 2.

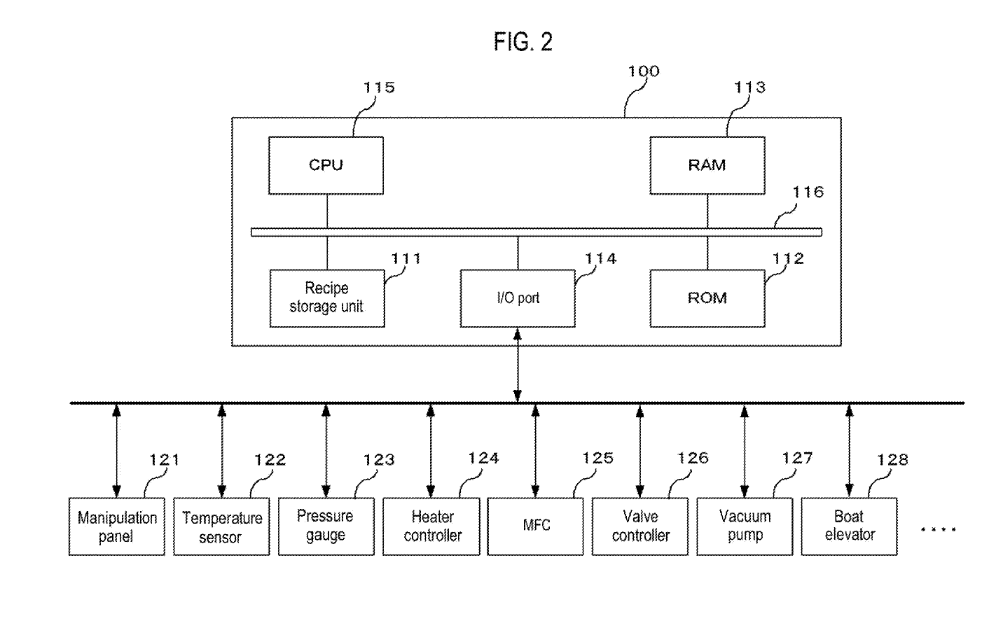

Furthermore, the processing apparatus 1 includes a controller 100 configured to control the respective components of the apparatus. FIG. 2 illustrates the configuration of the controller 100. As shown in FIG. 2, a manipulation panel 121, the temperature sensors 122, the pressure gauges 123, a heater controller 124, the MFC 125, valve controllers 126, the vacuum pump 127, the boat elevator 128 and the like are connected to the controller 100.

The manipulation panel 121 includes a display screen and operation buttons. The manipulation panel 121 transmits operation instructions of an operator to the controller 100 and displays various types of information received from the controller 100 on the display screen.

The temperature sensors 122 measure the temperatures of the respective components within the reaction tube 2 and the exhaust pipe, and notify the measurement to the controller 100.

The pressure gauges 123 measure the pressures of the respective components within the reaction tube 2 and the exhaust pipe, and notify the measurement to the controller 100.

The heater controller 124 individually controls the heaters 7. In response to instructions received from the controller 100, the heater controller 124 allows supply of electric current to the heaters 7 to start the heaters 7. Moreover, the heater controller 124 individually measures power consumption of the heaters 7 and notifies the measurement to the controller 100.

The respective MFC 125 is disposed in the source gas supply pipe 8, the nitriding gas supply pipe 9, and the nitrogen gas supply pipe 11. The MFC 125 controls flow rates of gases flowing through the respective pipes as amounts specified from the controller 100. In addition, the MFC 125 measures the flow rates of the actually flowing gases and notifies the measurement to the controller 100.

The valve controllers 126 are disposed in the respective pipes and control a degree of opening of the valves disposed in the respective pipes as the values specified from the controller 100.

The vacuum pump 127 is connected to the exhaust pipe and exhausts the gas present within the reaction tube 2.

The boat elevator 128 moves the lid 5 upward to load the wafer boat 6 (the semiconductor wafers W) to the interior of the reaction tube 2. The boat elevator 128 moves the lid 5 downward to unload the wafer boat 6 (the semiconductor wafers W) from the interior of the reaction tube 2.

The controller 100 includes a recipe storage unit 111, a read only memory (ROM) 112, a random access memory (RAM) 113, an input/output (I/O) port 114, a central processing unit (CPU) 115, and a bus 116 interconnecting these components to one another.

A setup recipe and a plurality of process recipes are stored in the recipe storage unit 111. Only the setup recipe is stored when the processing apparatus 1 is initially fabricated. The setup recipe is performed when a thermal model and the like according to each processing apparatus is generated. The process recipe is prepared in each heat treatment (process) actually performed by a user. Each of the process recipes defines temperature changes of the respective components, pressure changes within the reaction tube 2, and supply start/stop timings and supply amounts of various types of gases, from the time when the semiconductor wafers W are loaded into the reaction tube 2 to the time when the processed semiconductor wafers W are unloaded from the reaction tube 2.

The ROM 112 is constituted by an electrically erasable programmable read only memory (EEPROM), a flash memory, a hard disk or the like. The ROM 112 is a recording medium that stores an operation program of the CPU 115.

The RAM 113 serves as a work area of the CPU 115.

The I/O port 114 is connected to the manipulation panel 121, the temperature sensors 122, the pressure gauges 123, the heater controller 124, the MFC 125, the valve controllers 126, the vacuum pump 127, the boat elevator 128, and the like. The I/O port 114 controls the input and output of data and signals.

The CPU 115 constitutes a center of the controller 100 and executes operation programs stored in the ROM 112. Moreover, the CPU 115 controls operation of the processing apparatus 1 depending on the recipes (process recipes) stored in the recipe storage unit 111 in accordance with the instructions from the manipulation panel 121. That is to say, the CPU 115 allows the temperature sensors 122, the pressure gauges 123, and the MFC 125 and the like to measure the temperatures, pressures, and flow rates of the respective components within the reaction tube 2 and the exhaust pipe. Based on the measurement data, the CPU 115 outputs control signals to the heater controller 124, the MFC 125, the valve controllers 126, the vacuum pump 127, and the like, thereby controlling the respective components in accordance with the process recipes.

The bus 116 transmits information between the respective components.

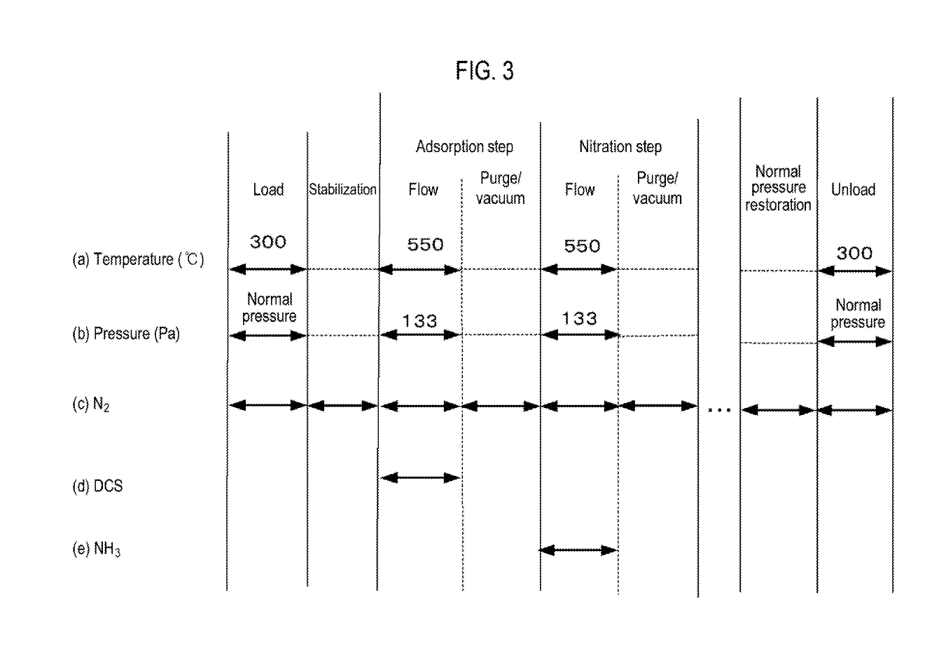

Next, a method of forming the silicon nitride film using the processing apparatus 1 configured as above will be described with reference to the recipe (time sequence) shown in FIG. 3. In the method of forming the silicon nitride film according to this embodiment, the silicon nitride film is formed on a semiconductor wafer W by an atomic layer deposition (ALD) method.

As shown in FIG. 3, the method according to this embodiment includes an adsorption step for adsorbing a source (Si) to the semiconductor wafer W and a nitriding step for nitriding the adsorbed source. A silicon nitride film having a desired thickness is formed on the semiconductor wafer W by performing (repeating) the adsorption step and the nitriding step plural times, for example, one hundred cycles. In addition, in this embodiment, as shown in FIG. 3, dichlorosilane (DCS) is used as a Si source gas, ammonia (NH₃) is used as the nitriding gas, and nitrogen (N₂) is used as the diluting gas.

Moreover, in the following description, operations of the respective components constituting the processing apparatus 1 are controlled by the controller 100 (the CPU 115). Further, the controller 100 (the CPU 115) controls the heater controller 124 (the heaters 7), the MFC 125 (the source gas supply pipe 8, etc.), the valve controllers 126, and the vacuum pump 127 in the aforementioned manner, such that the temperature, the pressure and the flow rates of gases within the reaction tube 2 in the respective processes are set to conditions conforming to the recipe shown in FIG. 3.

First, the interior of the reaction tube 2 is maintained at a predetermined loading temperature, for example, 300 degrees C., by the heaters 7, as shown in (a) of FIG. 3. A specific amount of nitrogen is supplied from the nitrogen gas supply pipe 11 into the reaction tube 2, as shown in (c) of FIG. 3. Next, the wafer boat 6 accommodating the semiconductor wafers W is mounted on the lid 5. Then, the lid 5 is moved up by the boat elevator 128, thereby loading the semiconductor wafers W (the wafer boat 6) into the reaction tube 2 (load process).

First, the interior of the reaction tube 2 is set to a predetermined temperature, for example, 550 degrees C., as shown in (a) of FIG. 3, by the heaters 7. Moreover, the gas is discharged from the reaction tube 2 while a specific amount of nitrogen is supplied from the nitrogen gas supply pipe 11 into the reaction tube 2. Thus, the internal pressure of the reaction tube 2 is set to a predetermined pressure, for example, 133 Pa (1 Torr), as shown in (b) of FIG. 3 (stabilization process).

In this regard, in some embodiments, the internal temperature of the reaction tube 2 may range from 100 degrees C. to 700 degrees C., in another embodiment, from 500 degrees C. to 600 degrees C. If the internal temperature of the reaction tube 2 is set in this range, the silicon nitride film can have further improved film quality and uniformity in terms of film thickness.

In some embodiments, the internal pressure of the reaction tube 2 may range from 0.133 Pa (0.001 Torr) to 13.3 kPa (100 Torr). If the internal pressure of the reaction tube 2 is set in this range, it is possible to accelerate reaction of Si with the semiconductor wafer W. In another embodiment, the internal pressure of the reaction tube 2 may range from 133 Pa (1 Torr) to 1330 Pa (10 Torr). If the internal pressure of the reaction tube 2 is set in this range, it is easy to control the internal pressure of the reaction tube 2.

Subsequently, the adsorption step for adsorbing a source to the semiconductor wafer W is performed. When the internal temperature and internal pressure of the reaction tube 2 are stabilized, a specific amount of DCS is supplied as the Si source from the source gas supply pipe 8, as shown in (d) of FIG. 3, while a specific amount of nitrogen is supplied from the nitrogen gas supply pipe 11 into the reaction tube 2, as shown in (c) of FIG. 3 (flow process).

DCS supplied into the reaction tube 2 is heated and activated within the reaction tube 2. For this reason, upon supplying DCS into the reaction tube 2, the activated Si reacts with the semiconductor wafer W and Si is adsorbed to the semiconductor wafer W.

When a predetermined amount of Si is adsorbed to the semiconductor wafer W, supplies of DCS from the source gas supply pipe 8 and nitrogen from the nitrogen gas supply pipe 11 are stopped. Then, while the gas within the reaction tube 2 is discharged, a specific amount of nitrogen is supplied from the nitrogen gas supply pipe 11 into the reaction tube 2, as shown in (c) of FIG. 3 (purge/vacuum process). Thus, the gas within the reaction tube 2 is discharged outside of the reaction tube 2.

Subsequently, the nitriding step for nitriding the source Si adsorbed to the semiconductor wafer W in the adsorption step is performed. In the nitriding step, first, the internal temperature of the reaction tube 2 is set to a predetermined temperature, for example, 550 degrees C., as shown in (a) of FIG. 3, by the heaters 7. Moreover, while a specific amount of nitrogen is supplied from the nitrogen gas supply pipe 11 into the reaction tube 2, the gas from the reaction tube 2 is discharged. Thus, the internal pressure of the reaction tube 2 is set to a predetermined pressure, for example, 133 Pa (1 Torr), as shown in (b) of FIG. 3. Then, while a specific amount of ammonia is supplied from the nitriding gas supply pipe 9, as shown in (e) of FIG. 3, a specific amount of nitrogen from the nitrogen gas supply pipe 11 is supplied into the reaction tube 2, as shown in (c) of FIG. 3 (flow process).

Herein, the interior (inner wall) of the nitriding gas supply pipe 9 is coated with platinum-group metals. Thus, when ammonia is supplied into the nitriding gas supply pipe 9, ammonia is decomposed by catalysis in the interior of the nitriding gas supply pipe 9 to thereby be activated. Moreover, the nitriding gas supply pipe 9 is arranged in the interior of the reaction tube 2. Thus, when ammonia is supplied into the nitriding gas supply pipe 9, ammonia is decomposed by thermal effect in the interior of the nitriding gas supply pipe 9 to thereby be activated. Accordingly, ammonia is decomposed by catalysis and thermal effect in the interior of the nitriding gas supply pipe 9 to thereby be activated. For these reasons, ammonia supplied from the nitriding gas supply pipe 9 is supplied into the reaction tube 2 (semiconductor wafers W) in the activated state. When the activated ammonia is supplied into the reaction tube 2, the adsorbed Si is nitrided.

When the adsorbed Si is nitrided, supplies of ammonia from the nitriding gas supply pipe 9 and nitrogen from the nitrogen gas supply pipe 11 are stopped. Then, while the gas within the reaction tube 2 is discharged, a specific amount of nitrogen is supplied from the nitrogen gas supply pipe 11 into the reaction tube 2, for example, as shown in (c) of FIG. 3. Thus, the gas within the reaction tube 2 is discharged outside of the reaction tube 2 (purge/vacuum process).

Accordingly, one cycle of ALD method including the adsorption step and the nitriding step is finished. Subsequently, another cycle of ALD method may be started from the adsorption step. Such a cycle may be repeated a predetermined number of cycles, for example, one hundred cycles. As a result, a silicon nitride film having a desired thickness is formed on the semiconductor wafer W.

When the silicon nitride film having a desired thickness is formed on the semiconductor wafer W, a specific amount of nitrogen is supplied from the nitrogen gas supply pipe 11 into the reaction tube 2, while the interior of the reaction tube 2 is maintained at a predetermined loading temperature, for example, 300 degrees C., by the heaters 7, as shown in (a) of FIG. 3. Thus, the interior of the reaction tube 2 is cycle-purged with nitrogen to be returned to normal pressure (normal pressure restoration process). Then, the lid 5 is moved down by the boat elevator 128, thereby unloading the semiconductor wafers W (unloading process).

In this manner, since the interior of the nitriding gas supply pipe 9 is coated with platinum-group metals, ammonia as the nitriding gas is activated, whereby it is possible to nitride the source Si adsorbed to the semiconductor wafer W.

Next, in order to confirm the effect of the present disclosure, in case the interior (inner wall) of the nitriding gas supply pipe 9 is coated with platinum-group metals, and in case of an uncoated nitriding gas supply pipe, a process including the adsorption step and the nitriding step in the aforementioned method of forming silicon nitride film is repeated one hundred cycles. Then, film thicknesses of the silicon nitride films formed on the semiconductor wafers (W) were measured. As a result, it was confirmed that the film thicknesses of the silicon nitride film formed by using the nitriding gas supply pipe 9, which is coated with platinum-group metals, becomes 1.5 times to 2.8 times thicker than that of the silicon nitride film formed by using the uncoated nitriding supply pipe. It was also confirmed that the silicon nitride film, which is formed by using the coated nitriding gas supply pipe 9, has excellent in-plain uniformity and inter-plane uniformity.

As describe above, according to this embodiment, the interior (inner wall) of nitriding gas supply pipe 9 is coated with platinum-group metals, whereby the silicon nitride film having high-quality can be formed at a low temperature without causing plasma damage.

Moreover, the present disclosure is not limited to the aforementioned embodiment but may be modified and applied in many different forms. Hereinafter, other embodiments applicable to the present disclosure will be described.

In the aforementioned embodiment, the present disclosure has been described by way of an example wherein the interior (inner wall) of the nitriding gas supply pipe 9 is coated with platinum-group metals. Alternatively, members, for example, such as the inner wall of the reaction tube 2, the wafer boat 6 and dummy wafers, arranged in a flow path where ammonia supplied into the reaction tube 2 flows until reaching the semiconductor wafer W may be coated with platinum-group metals. By coating these members with platinum-group metals, the activated ammonia can be supplied to the semiconductor wafer W. Moreover, in some embodiments, if the inner wall of the reaction tube 2, the wafer boat 6 or the like is coated with quartz, the surface thereof may be roughened so as to have a large surface area rather than to have smoothness, for example, by sand blast processing. This is because the absolute amount of ammonia gas in contact with catalysts before being supplied to a chamber increases and then the decomposition catalytic effect also increases.

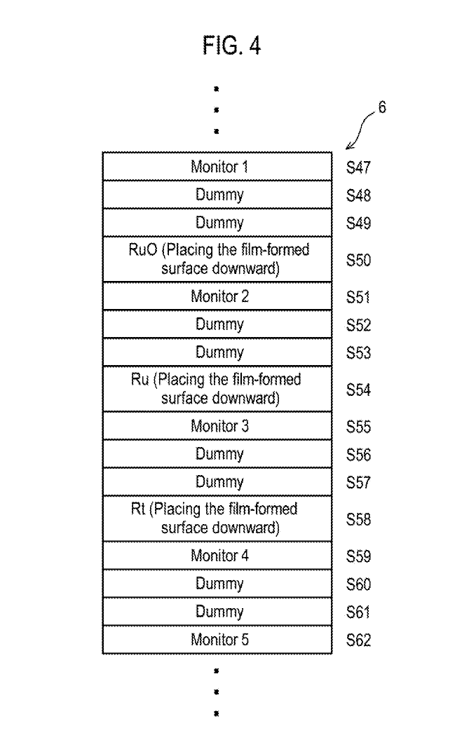

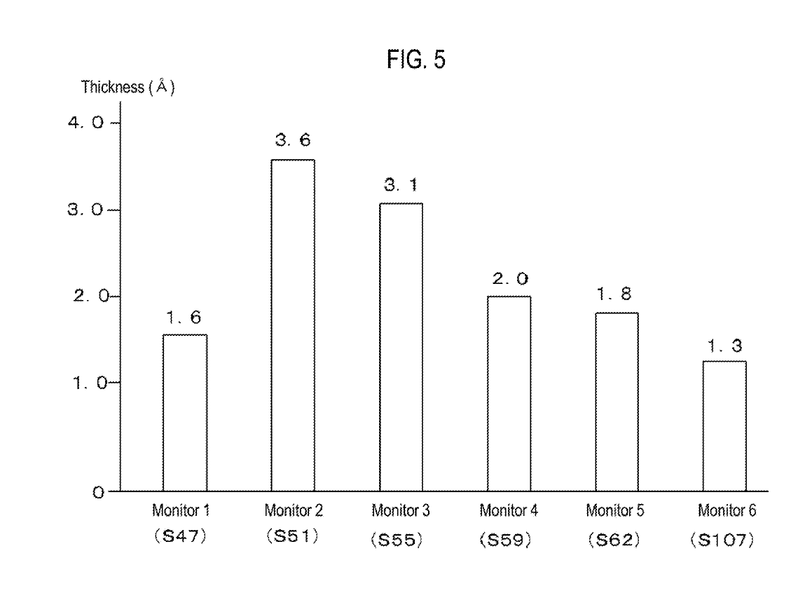

For example, as shown in FIG. 4, silicon nitride films are formed by arranging wafers coated with platinum-group elements Ru and Pt, oxide of RuO and the like in the wafer boat 6. Then, film thicknesses of the silicon nitride films formed on monitor wafers are measured. FIG. 5 illustrates thicknesses of the silicon nitride films formed on the monitor wafers for each location, respectively. As shown in FIG. 5, it was confirmed that film thicknesses of monitor wafers, which are located near the wafers coated with platinum-group elements, oxides of platinum-group metals and the like, are 1.2 times to 2.3 times thicker than that of other monitor wafers. Moreover, it was confirmed that the silicon nitride film has excellent in-plane uniformity and inter-plane uniformity. Accordingly, it is possible to form the silicon nitride film having high-quality at a low temperature without causing the plasma damage. Furthermore, a sufficient nitration property can be obtained in a shorter time than a conventional method, or a plasma treatment condition can be changed to a lower condition where the plasma damage does not occur. Thus, it is possible to deal with processes which have not been applied in terms of the plasma damage.

In the aforementioned embodiment, the present disclosure has been described by way of an example wherein DCS is used as the Si source. However, the Si source may be any silicon (Si) containing gas, for example, hexachlorodisilane (HCD: Si₂Cl₆) or tetrachlorosilane (SiCl₄).

In the aforementioned embodiment, the present disclosure has been described by way of example wherein one cycle composed of a single adsorption step and a single nitriding step is repeated one hundred cycles. As an alternative example, the number of cycles may be reduced to, for example, fifty cycles. Moreover, the number of cycles may be increased to, for example, two hundred cycles.

In the aforementioned embodiment, the present disclosure has been described by way of an example wherein the silicon nitride film is formed on the semiconductor wafer W by using ALD method. However, the present disclosure is not limited to the example using ALD method. The silicon nitride film may be formed on the semiconductor wafer W by using a CVD (Chemical Vapor Deposition) method.

In the aforementioned embodiment, the present disclosure has been described by way of an example wherein nitrogen is supplied as the diluting gas during supply of the process gas such as DCS or the like. Alternatively, the diluting gas may not be supplied during supply of the process gas. However, by containing nitrogen as the diluting gas, it is easy to set the processing time and the like. Therefore, it is suitable to use nitrogen as the diluting gas. The diluting gas may be an inert gas other than nitrogen, for example, helium (He), neon (Ne), argon (Ar), krypton (Kr), or xenon (Xe).

In the aforementioned embodiment, the present disclosure has been described by way of an example wherein the batch-type processing apparatus having a double tube structure is used as the processing apparatus 1. However, as an alternative example, the present disclosure may be applied to a batch-type processing apparatus having a single tube structure. Moreover, the present disclosure may be applied to a batch-type horizontal processing apparatus or a single-substrate-type processing apparatus.

The controller 100 according to embodiments of the present disclosure may be realized using a typical computer system instead of a dedicated computer system. For example, the controller 100 for performing the aforementioned processes may be configured by installing programs for executing the aforementioned processes into a general-purpose computer through a recording medium (a flexible disk, a compact disc-read only memory (CD-ROM), or the like) which stores the programs for performing the aforementioned processes.

Moreover, the programs may be provided by arbitrary means. The programs may be provided not only by the recording medium mentioned above but also through a communication line, a communication network, a communication system or the like. In the latter case, the programs may be posted on a bulletin board system (BBS) of the communication network and provided through a network. Moreover, it is possible to perform the aforementioned process, by starting and executing the provided program under the control of an operating system (OS) similar to other application programs.

According to the present disclosure, it is possible to form a silicon nitride film having high-quality at a low temperature without causing plasma damage.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An apparatus for forming a silicon nitride film, comprising:
a reaction chamber accommodating a workpiece;
a source gas supply unit configured to supply a source gas containing silicon into the reaction chamber;
a nitriding gas supply unit configured to supply a nitriding gas into the reaction chamber;
a controller configured to form the silicon nitride film on the workpiece by controlling the source gas supply unit such that the silicon is adsorbed to the workpiece accommodated in the reaction chamber by supplying the source gas into the reaction chamber, and controlling the nitriding gas supply unit such that the silicon adsorbed to the workpiece is nitrided by supplying the nitriding gas into the reaction chamber;
a flow path where the nitriding gas supplied into the reaction chamber flows until reaching the workpiece; and
members arranged in the flow path, the members having a coating with platinum-group metals that activates the nitriding gas supplied from the nitriding gas supply unit.

2. The apparatus of claim 1, wherein an inner wall of a supply pipe of the nitriding gas supply unit is coated with the platinum-group metals.

3. The apparatus of claim 1, wherein the controller is configured to form the silicon nitride film by repeating a process plural times, and
wherein the process includes: controlling the source gas supply unit such that the silicon is adsorbed to the workpiece accommodated in the reaction chamber by supplying the source gas into the reaction chamber; and controlling the nitriding gas supply unit such that the silicon adsorbed to the workpiece is nitrided by supplying the nitriding gas into the reaction chamber.

4. The apparatus of claim 1, wherein the platinum-group metals comprise platinum-group elements including: ruthenium; rhodium; palladium; osmium; iridium; and platinum, and oxides of the platinum-group elements.

5. The apparatus of claim 1, wherein the nitriding gas is ammonia.

6. The apparatus of claim 1, further comprising a heater configured to heat an interior of the reaction chamber at a predetermined temperature,
wherein the controller is configured to heat the interior of the reaction chamber at a temperature ranging from 100 degrees C. to 700 degrees C. by controlling the heater.

7. A method of forming a silicon nitride film, comprising;
adsorbing silicon to a workpiece by supplying a silicon source gas containing silicon into a reaction chamber accommodating the workpiece and activating the supplied silicon source gas to react the activated silicon source gas with the workpiece; and
nitriding by supplying a nitriding gas into the reaction chamber, activating the supplied nitriding gas, and reacting the activated nitriding gas with silicon adsorbed to the workpiece,
wherein, in nitriding, the supplied nitriding gas is activated by coating members arranged in a flow path where the nitriding gas supplied into the reaction chamber flows until reaching the workpiece with platinum-group metals.

8. The method of claim 7, wherein the silicon nitride film is formed by repeating adsorbing and nitriding sequentially plural times.
